(19) United States
(12) Patent Application Publication
(10) Pub. No.: US 2011/0115487 A1
(43) Pub. Date: May 19, 2011

(54) METHOD AND MAGNETIC RESONANCE SYSTEM FOR IMAGING PARTICLES

(76) Inventor: David Grodzki, Hannover (DE)

(21) Appl. No.: 12/942,110

(22) Filed: Nov. 9, 2010

(30) Foreign Application Priority Data
Nov. 13, 2009 (DE) 10 2009 053 293.5

(51) Int. Cl. G01R 33/48

(52) U.S. Cl. 324/309

(57) ABSTRACT

A method and magnetic resonance system for imaging a particle that is located in an examination subject with an imaging magnetic resonance measurement execute a gradient echo sequence in which at least two gradient echoes are acquired following a single excitation pulse, wherein the particle in an applied basic magnetic field causes a magnetic interference field. An RF pulse is radiated to generate a transverse magnetization from a magnetization appearing in the basic magnetic field. A first dephasing gradient is shifted to adjust a first dephasing of the transverse magnetization, and the first gradient echo is acquired. A second dephasing gradient is shifted to adjust a second dephasing of the transverse magnetization that is different than the first dephasing, and the second gradient echo is acquired. The two dephasing gradients are shifted such that a dephasing of the transverse magnetization caused by the interference field of the particle is at least partially compensated in a region around the particle or within the particle given the acquisition of at least one of the echoes.

### BACKGROUND OF THE INVENTION

1. Field of the Invention

The present invention concerns a method to image a particle that is located in an examination subject, as well as a magnetic resonance system for this purpose. The invention in particular concerns the imaging of a particle that causes a magnetic interference field in an applied basic magnetic field in a magnetic resonance measurement (scan).

2. Description of the Prior Art

Magnetic resonance tomography (MRT) is a modality in widespread use to graphically depict structures inside the body of a patient. To generate a magnetic resonance (MR) signal, in general protons of hydrogen molecules that are found in a prepared, magnetic state are excited. The decay of this excitation induces the MR signal in an acquisition coil. The MR signal is thus dependent on, among other things, the density of the protons of the hydrogen molecules. A very low magnetic resonance signal—which leads to a depiction of the corresponding regions in the magnetic resonance images as a dark point (“void”)—is thereby acquired from regions to be imaged in which the proton density is very low, for example from air-filled regions or from the bones. Such dark points in magnetic resonance images can also be caused by other mechanisms, for example local magnetic fields that lead to a dephasing of the excited magnetization and thus generate what is known as a hypointense contrast.

This hypointense contrast can be utilized to depict probes in the form of particles into which magnetically active substances are integrated. Such particles have a number of applications in the clinical routine and in research, for example in the field of pharmaceutical carrier systems (drug delivery). Due to their magnetic activity, these tracer particles cause a magnetic interference field, for example a dipole field, upon the application of the basic magnetic field of a magnetic resonance measurement, so they are imaged with hypointense contrast and can consequently be localized. Particularly in T2*-weighted gradient echo (GRE) sequences, the interference of the homogeneous basic magnetic field leads to a signal loss.

One problem in this type of imaging of particles is that the hypointense image regions cannot be unambiguously associated with the particles since—as described above—there are multiple causes for a poor signal and corresponding dark image regions.

To solve this problem, in the prior art methods are known that generate a hyperintense contrast. These methods utilize the magnetic dipole field of the particles that, in the immediate environment of the particles, causes a magnetic field gradient that leads to a change of the Larmor frequencies of the protons in this environment relative to their appearance. Such a method is described in the publication “Dephased MRI”, Chris J. G. Bakker et al., Magn. Reson. Med., 2006 January, 55 (1), P. 92, for example, in which a hyperintense contrast is generated in the environment of interfering particles. The method is GRE-based and generates an artificial dephasing that leads to a signal loss in the undistorted protons of the water molecules. A rephasing of the spins disrupted by the dipole field of the particles is achieved via suitable adjustment of the artificial dephasing, such that an MR signal is acquired from these regions. Multiple images with different GRE sequences in which different dephasings are adjusted are acquired to image the particles. An image with increased contrast in which the particles are identifiable is obtained by subtraction of two images of different dephasing stages.

Such a procedure has the disadvantage of requiring long measurement times. Furthermore, due to the doubling of the measurement time the method is strongly susceptible to movements of the examined subject or patient, such that the acquired images contain movement artifacts. Particularly in the subtraction of images, movements of the patient lead to image errors and thus to a loss of resolution and contrast in the imaging of the particles.

### SUMMARY OF THE INVENTION

An object of the present invention is to avoid at least some of the aforementioned disadvantages and to improve the imaging of particles that are located in an examination subject.

According to a first aspect of the present invention, a method is provided for imaging a particle that is located in an examination subject with an imaging magnetic resonance measurement, wherein the magnetic resonance measurement is implemented with a gradient echo sequence in which at least two gradient echoes are acquired following a single excitation pulse. In the magnetic resonance measurement, the particles in an applied basic magnetic field cause a magnetic interference field. The method includes the following steps. An RF pulse is radiated to generate a transverse magnetization relative to the magnetization produced by the basic magnetic field. A first dephasing gradient is shifted to adjust a first dephasing of the transverse magnetization, and a first gradient echo is carried. A second dephasing gradient is shifted to adjust a second dephasing of the transverse magnetization, which is different than the first dephasing, and a second gradient echo is acquired. The two dephasing gradients are shifted such that a dephasing of the transverse magnetization caused by the interference field of the particle is at least partially compensated in a region around the particle or within the particle during the acquisition of at least one of the echoes.

Different, adjustable dephasing strengths can consequently be generated by shifting the dephasing gradients. Different dephasing stages thus can be acquired in one measurement, from which a marked time gain results. Since the first and second echoes can be acquired within a short span of time, artifacts due to movements of the examination subject are minimized. The time gain can be achieved when no additional excitation pulses are radiated between the radiation of the excitation pulse and the acquisition of the second gradient echo. An at least partial compensation is sufficient to achieve a hypointense contrast in the imaging of the particle, meaning that the compensation has to take place only in a portion of the region or of the particle.

According to one embodiment of the present method, the first and second dephasing gradients are shifted along the same gradient direction with the same or opposite polarity. For example, the first and second dephasing gradients can be switched along the slice selection direction, the frequency coding direction or the phase coding direction. It is therefore possible to generate contrast for imaging the particle in different ways. The dephasing of the transverse magnetization that is caused by the interference field can be compensated in different directions. In another embodiment, shifting of the dephasing gradients in different directions is also possible, so the first dephasing can initially be compensated before adjusting the second.

The first and second dephasing gradients furthermore can be shifted such that the second dephasing gradient compensates the first dephasing and subsequently generates the second dephasing. In particular, the dephasing gradients can be shifted such that a gradient of the phase position of the transverse magnetization after the adjustment of the first phasing exhibits a polarity sign that is inverted relative to the sign than after the adjustment of the second dephasing. The directions of the first and second dephasing can thus be opposite, which can be expressed by a positive or negative dephasing strength. Given such a configuration a particularly good contrast can be achieved, in particular in a difference image from the images acquired in the first and second dephasing.

However, it is also possible for the first or second dephasing to be set to zero (dephasing strength σ=0), such that the transverse magnetization is rephased after the first or second dephasing gradient. A reference image thus can be obtained from the data or dephasing acquired in the first or second gradient echo, with which data or dephasing the contrast of the particle to be imaged can be increased in the corresponding image data acquired with dephasing, for example by means of subtraction or addition of the images.

In one embodiment the first dephasing gradient can embody a dephasing gradient and a rephasing gradient, and the first dephasing of the transverse magnetization can be adjusted by means of a difference between the gradient moment of the rephasing gradient and the gradient moment of the dephasing gradient. For example, an insufficient compensation or an overcompensation of the dephasing of the transverse magnetization that is caused by the dephasing gradient occurs by means of the rephasing gradient, such that the resulting first dephasing remains. The first dephasing gradient thus can be integrated into the gradient echo sequence in a simple manner, whereby an additional time savings results. The dephasing gradient of the first dephasing gradient can be shifted, for example, in the slice selection direction during the radiation of the RF pulse. It can therefore serve as a slice selection gradient.

The respective rephasing gradients of the first dephasing gradient and the second dephasing gradient can be shifted in opposite directions. The second dephasing gradient thus can compensate a dephasing impressed by the rephasing gradients.

Naturally, it is likewise possible for the first dephasing gradient to be shifted as an additional gradient in an arbitrary direction.

In a further embodiment of the method according to the invention, additional readout steps that respectively include the shifting of a dephasing gradient and the acquisition of a gradient echo follow the acquisition of the second gradient echo. In each readout step a different dephasing of the transverse magnetization can then be set, such that a different dephasing stage is acquired with each gradient echo. Naturally a dephasing stage can in turn be acquired with a dephasing strength of σ=0. The provision of additional readout steps leads to an additional time savings and therefore to an additional reduction of movement-induced image interference.

For each of the adjusted dephasings, image data that image the particle or a region around the particle with different contrast can be reconstructed from the acquired gradient echo. Naturally, scanning of k-space can ensue by implementing multiple measurements with different phase coding for the respectively adjusted dephasings. A measurement for a phase coding is sufficient in order to acquire a k-space line for different dephasing stages, from which correspondingly many image data sets can be reconstructed. From this, the selection of a dephasing stage that shows the particles to be imaged with optimally good contrast can take place.

Furthermore, it is possible to determine combined image data by addition or subtraction of image data for at least two different dephasings. The contrast of the depiction can be increased by targeted addition or subtraction of the image data for different dephasing stages. Since the echoes can exhibit a slice time interval—for example of a few milliseconds—measurement errors due to movements of the examination subject are minimized.

The particle to be imaged can be a magnetically active particle, for example. The particle can be or include iron oxide. The particle can in particular include superparamagnetic nanoparticles made of iron oxide. The imaging of particles with different structure or different composition that cause a magnetic interference field upon application of a basic magnetic field is naturally also possible.

According to a further aspect of the present invention, a magnetic resonance system is provided that is designed to image a particle that is located in an examination subject with an imaging magnetic resonance measurement. The magnetic resonance system has a magnet that is designed to apply a basic magnetic field; an RF coil arrangement that is designed to radiate RF pulses; a gradient system that is designed to shift magnetic field gradients; and a control unit that is designed in order to activate the magnet, the RF arrangement and the gradient system to implement a gradient echo sequence in which at least two gradient echoes are acquired following a single excitation pulse. The control unit is designed to initiate the implementation of the following Steps: apply the basic magnetic field by means of the magnet, wherein the particle induces a magnetic interference field in the applied basic magnetic field; radiate an RF pulse by means of the RF coil arrangement to generate a transverse magnetization from a magnetization appearing in the basic field; shift a first dephasing gradient by means of the gradient system to adjust a first dephasing of the transverse magnetization; acquire the first gradient echo; shift a second dephasing gradient by means of the gradient system to adjust the second dephasing of the transverse magnetization that is different than the first dephasing; and acquire the second gradient echo. The at least two dephasing gradients are shifted such that a dephasing of the transverse magnetization that is caused by the interference field of the particle is compensated at least partially in a region around the particle or inside the particle given the acquisition of at least one of the echoes.

Advantages similar to those cited above can be achieved with a magnetic resonance system of such a design. The magnetic resonance system can furthermore be designed to implement one of the methods cited in the preceding.

The invention furthermore concerns a non-transitory readable data storage medium with electronically readable control information stored thereon, which control information is designed such that it executes the aforementioned methods upon use of the data medium in a computer system. For example, the computer system can be functionally connected with a magnetic resonance system.

Naturally, the features of the aspects and embodiments of the invention that are described above and in the following can be combined.

### BRIEF DESCRIPTION OF THE DRAWINGS

FIG. 1 is a schematic block diagram of an embodiment of the magnetic resonance system according to the invention.

FIG. 2 is a flow diagram of an embodiment of the method according to the invention.

FIG. 3 illustrates a gradient echo sequence according to an embodiment of the method according to the invention.

FIG. 4 shows two images of a magnetically active particle that were created with different dephasings, and a difference image.

FIG. 5 shows a numerical simulation of the images shown in FIG. 4.

FIG. 6 shows images of sample vessels with different particle density that were acquired for different dephasing stages, and a difference image.

FIG. 7 shows images of sample vessels with different particle density that were acquired for different dephasing stages, and a difference image.

### DESCRIPTION OF THE PREFERRED EMBODIMENTS

The imaging of magnetically active particles that generate an interference field (for example a dipole field) in an applied basic magnetic field is explained in detail using the embodiments of the present invention that are described in the following. In the gradient echo-based method, the dipole field generated by the particle is compensated via targeted dephasing in the readout, phase or slice coding direction in order to thus obtain an increased signal of protons that are located in the disrupted basic magnetic field. At the same time a weakened MR signal of the undistorted protons is acquired via the dephasing, such that the particle to be imaged can be shown with high contrast. The dephasing can be adjusted by uncompensated dephasing and rephasing gradients or via additional dephasing gradients. The strength of this adjustable dephasing can be specified in the unit “cycles per voxel (CpV)”, for example. A dephasing of the strength 1 CpV indicates that the phase difference of the spins that precess around the axis (z) of the basic magnetic field in the excited state amounts to one revolution (thus 2π) over a voxel along the corresponding dephasing direction. For each spin alignment there is accordingly an opposite spin alignment across the voxel in the transverse direction, such that the MR signals acquired from the voxel cancel out completely if this voxel is located in the undistorted basic magnetic field. Thus no MR signal would be obtained from this voxel. For example, if the basic magnetic field is distorted by the dipole field, the signals do not mutually cancel out, such that the voxel can be imaged with the aid of the resulting MR signal.

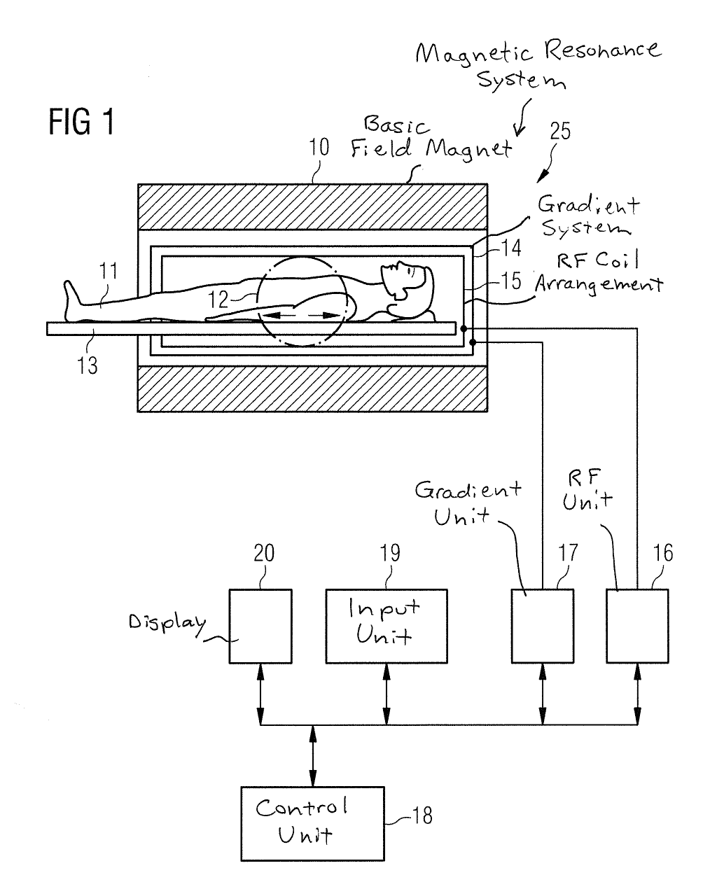

FIG. 1 schematically shows a magnetic resonance system 25 which is configured to implement gradient echo sequences to image magnetically active particles. Such a magnetic resonance system has a basic field magnet 10 to generate a polarization field B₀. An examination subject—here an examined person 11—can be slid on a bed table 13 into the magnet 10, as is schematically represented by the arrows. The MR system furthermore has a gradient system 14 to generate magnetic field gradients that are used for the imaging and spatial coding. In particular, with the gradient system 14 gradients can be shifted that serve to generate a gradient echo. The strength and the time shift of the applied gradients thereby significantly determines the gradient moment and therefore the degree or, respectively, the strength of the dephasing that is caused by the shifting of the gradient. The shifting of the gradient can ensue in various spatial directions for slice selection, phase coding or frequency coding. By means of the gradient system 14 it is accordingly possible to dephase an excited, transverse magnetization in an arbitrary direction.

A radio-frequency (RF) coil arrangement 15 is provided to excite the polarization that appears in the basic magnetic field B₀ of the MR system 25, which basic magnetic field B₀ is generated by the magnet 10. This radio-frequency coil arrangement 15 radiates a radio-frequency field (in the form of an RF pulse, for example) into the examined person 11 in order to deflect the magnetization from the equilibrium [steady] state. Excitation pulses with different flip angles can be radiated that lie, for example, between >0° and 90°. Via deflection of the magnetization resulting in the basic magnetic field (for example in the z-direction), a transverse magnetization (for example in the xy-direction) is generated whose decay can be detected as an induction by means of acquisition coils, wherein the acquisition coils can also be part of the RF coil arrangement 15. Naturally it is likewise possible to provide separate acquisition coils, for example head coils, body coils or the like.

In the implementation of a gradient echo sequence a gradient is now initially shifted that dephases magnetization (transversal after excitation) in a predetermined manner. By shifting an opposite gradient, the magnetization rephases, so the echo can be generated and the acquisition of a corresponding MR signal is enabled. The areas under the opposite gradients in the sequence diagram are thereby normally of the same size (identical gradient moment) in order to produce the complete rephasing of the magnetization. The acquisition of the MR signal thereby ensues during the free induction decay (FID) of the transverse magnetization.

A gradient unit 17 is provided to control the magnetic field gradient and an RF unit 16 is provided to control the radiated RF pulses.

MR signals from the examination region 12 can be acquired by means of the RF coil arrangement 15 and the RF unit 16. The control unit 18 centrally controls the magnetic resonance system, for example the implementation of a predetermined imaging gradient echo sequence. A selection of the imaging sequence to be implemented can ensue with the input unit 19. Control information—for example imaging parameters—as well as reconstructed MR images can be displayed on the display 20. Parameters to adjust a targeted dephasing can also be selected via the input unit, for example a dephasing strength a for a specific gradient direction. The control unit 18 can furthermore include a computer to reconstruct images from acquired MR signals, which computer can also implement further image processing steps such as the combination of two images into one contrast-enhanced image.

In contrast to conventional magnetic resonance systems, in the present embodiment of the magnetic resonance system according to the invention the control unit 18 is now designed such that it initiates the acquisition of at least two gradient echoes for different dephasing strengths following the radiation of one excitation pulse. The strength and direction of the dephasing upon readout of the first gradient echo can accordingly differ and be independent of the direction and strength of the dephasing upon readout of the second gradient echo. Different contrasts can thus be generated in the imaging of the particle, which different contrasts lead to an increased contrast overall in a subsequent image processing with the computer. It is likewise possible to set the strength of the dephasing in the acquisition of one of the echoes to zero, whereby a reference image is obtained in which the particles are shown with hypointense contrast, i.e. as dark regions. For example, dephasings in different strengths and different spatial directions can be generated in that after the acquisition of the first gradient echo the control unit 18 initiates the application of a gradient to rephase the first dephasing and furthermore initiates the application of a second dephasing gradient to adjust the dephasing for the second gradient echo. By adjusting different dephasing strengths, different dephasing stages can thus be acquired with one excitation in a single MR measurement. The measurement can thus be implemented within a very brief time period, such that movements of the examined person 11 are minimal and corresponding differences in the acquisition of the first echo and second echo are negligible. The particles can be imaged not only with increased contrast with the MR system 25, but also with a time gain and the consequent avoidance of measurement errors due to movements of the examined person 11.

The magnetic resonance system schematically shown in FIG. 1 can naturally include additional components that magnetic resonance systems conventionally possess. The general mode of operation of an MR system is known to those skilled in the art, such that a more detailed description of the general components is not necessary herein.

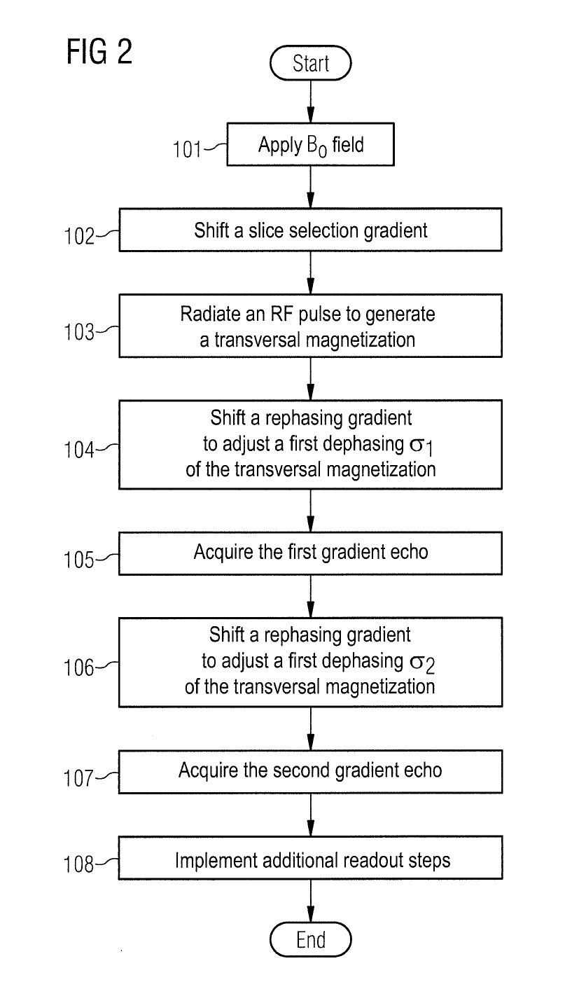

In particular, the magnetic resonance system 25 can be designed to implement the following method described with reference to FIG. 2.

FIG. 2 shows a flow diagram of an embodiment of the method according to the invention for imaging magnetically active particles, for example tracer particles. The application of a basic magnetic field B₀ (for example by means of the magnet 10) ensues in a first step 101. The examination subject in which the particles to be imaged are located is arranged in the basic magnetic field. The shifting of a slice selection gradient—for example in the z-direction—initially follows in Step 102 for the targeted imaging of a slice. An RF pulse is radiated in Step 103 to deflect the magnetization appearing in the B₀ field. In regions in which the Larmor frequency of the precessing proton spins coincides with the frequency of the radiated excitation pulse, the magnetization is therefore at least partially aliased in the x/y plane and thus generates a transverse magnetization. In conventional methods, the switching of a dephasing gradient with half the moment of the slice selection gradient is provided to compensate for the dephasing appearing due to the shifted slice selection gradient. In the present method, however, the dephasing is not completely compensated; rather a remaining first dephasing σ₁ is specifically adjusted. This ensues in Step 401 by switching a rephasing gradient with adjustable gradient moment.

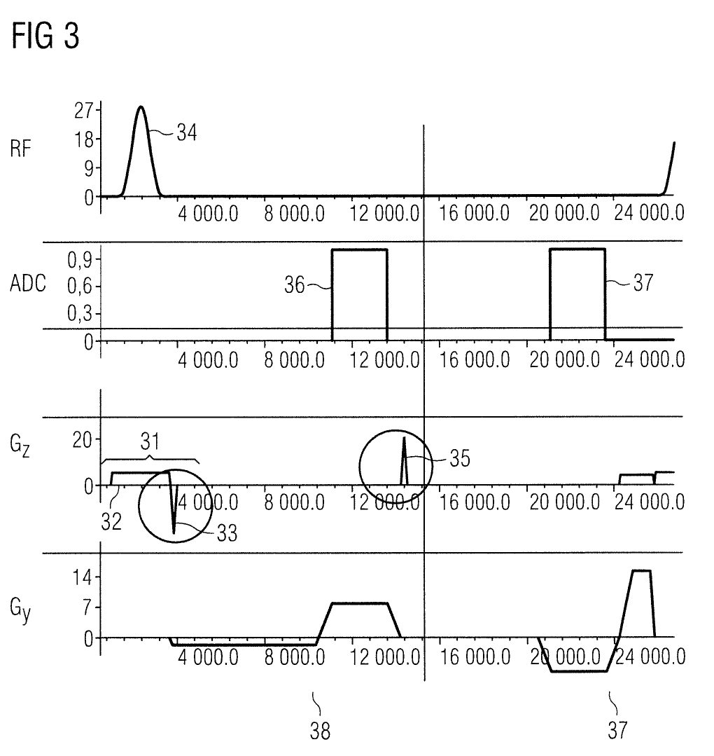

This is illustrated by way of example in FIG. 3. During the radiation of the RF pulse 34 to excite the magnetization, a slice selection gradient 32 is shifted in the slice selection direction G_{z}, which leads to a dephasing of the excited transverse magnetization in the z-direction. The rephasing gradient 33 is shifted for a partial compensation of the adjusted dephasing, wherein this does not completely compensate the dephasing, such that a residual dephasing with the dephasing strength σ₁ remains. This dephasing strength can be adjusted over the difference of the gradient moment of the dephasing gradient or, respectively, slice selection gradient 32 and the rephasing gradient 33. Since both gradients lead to an effective remaining dephasing, they can also be designated as a first dephasing gradient 31. Naturally it is also possible to completely compensate the dephasing caused by the slice selection gradient 32 and to subsequently shift a dephasing gradient in an arbitrary direction to adjust a predetermined first dephasing strength σ₁.

Referring again to FIG. 2, the acquisition of the first gradient echo ensues in the next step 105. This acquisition process is identified in FIG. 3 with the reference character 36 in which the MR signal is sampled. The gradient echo is generated by shifting the gradient 38 in the gradient direction G_{y}. The generation of a gradient echo is known to those skilled in the art and moreover has been explained above, such that a more detailed description is omitted here.

According to the invention at least one additional gradient echo is now generated and acquired in a preset dephasing after the acquisition of the first gradient echo, wherein a second dephasing can in turn be specifically adjusted in an arbitrary direction and strength in the acquisition. The shifting of a second dephasing gradient 35 ensues in Step 106 to adjust the second dephasing with the strength σ₂. In the present example, the transverse magnetization is thereby again adjusted to a predetermined dephasing in the z-direction (slice selection direction). The remaining first dephasing can be partially compensated, completely compensated or overcompensated. The second dephasing can accordingly have the same direction or an opposite direction, or it can even amount to zero, meaning that the magnetization can rephase given a complete compensation. If the first dephasing is overcompensated, the change of the phase position of the transverse magnetization exhibits an inverted polarity sign in the same direction. As mentioned, if the second dephasing is completely independent of the first dephasing it can ensue with arbitrary adjustable strength and in an arbitrary direction, wherein in this case an additional gradient is advantageously shifted to compensate for the remaining first dephasing.

The acquisition of the second gradient echo ensues in Step 107 after the adjustment of the second dephasing σ₂. This is identified with the reference character 37 in FIG. 3. The shifting of gradient 39 in the gradient direction G_{y} thereby ensues in turn to generate the gradient echo to simultaneously impress a frequency coding.

Additional gradients can be shifted after the acquisition of the second echo, for example to destroy a remaining magnetization (spoiler gradients). Additional measurements—for example with a different phase coding; not shown) can be conducted following this in order to acquire additional k-space lines. MR signals for two different dephasings can thus be acquired with one scan of k-space, from which MR signals two sets of image data can accordingly be reconstructed that show the particles to be imaged with different contrast.

As is illustrated in FIG. 2, however, the implementation of additional readout steps (Step 108) is also possible. The shifting of a dephasing gradient to adjust a predetermined dephasing and the acquisition of a gradient echo thereby respectively ensue as described with reference to Step 106 and 107. The number of acquirable dephasing stages in a single MR measurement can thus be additionally increased. A considerable time advantage can thereby be achieved overall since both the radiation of excitation pulses and the shifting of spoiler gradients between the acquisitions can be omitted. Furthermore, the measurements at the different dephasing stages exhibit a narrow time coverage, such that (as mentioned above) movements of the examined person are negligible.

It should again be noted that the dephasing can be adjusted in arbitrary direction and with arbitrary dephasing strength before the acquisition of each gradient echo. Via corresponding shifting of the gradients the dephasing can even be set to zero in order to acquire a conventional MR image with an imaging of the remaining structures.

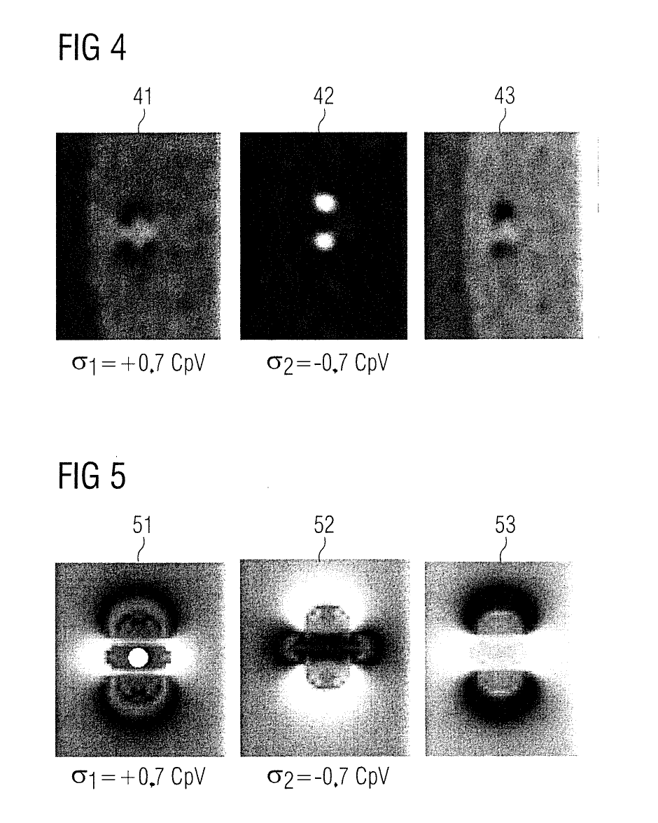

In an image processing step in FIG. 2 (not shown), the images acquired in different dephasing stages can be combined corresponding to the respective application, for example via addition or subtraction. This is subsequently illustrated more precisely with reference to FIGS. 4 through 7.

The method shown in FIG. 2 can naturally comprise additional steps that are known from a conventional gradient echo sequence. The method can be combined with most known gradient echo sequences. For example, methods with variable flip angle can also be used. The method is advantageously implemented within the scope of a flash (Fast Low Angle Shot) gradient echo sequence. These enable very short measurement times via use of small flip angles.

FIGS. 4, 6 and 7 described in the following show MR images that have been reconstructed from MR signals that were acquired with the method and the magnetic resonance system described in the preceding.

FIG. 4 shows the imaging of magnetically active particles in the form of small hollow spheres with a diameter of 0.3 mm. The small hollow spheres are marked with 81 ng of iron oxide that, due to its magnetic properties, causes an interference field if the small spheres are brought into the basic magnetic field B₀ of the magnetic resonance system. For example, superparamagnetic iron oxide particles with a size of a few nanometers can be used for the marking. The MR images 41 and 42 show coronal exposures of a hollow sphere. Image 41 was reconstructed from the MR signals acquired for the first gradient echo, wherein a dephasing of the strength σ₁=+0.7 CpV was set. The MR image 42 was reconstructed from the MR signals acquired for the second gradient echo, wherein here a dephasing in the opposite direction was set with a strength σ₂=−0.7 CpV. In particular in the MR image 42, the dephasing caused by the interference field of the particle is compensated by the specifically adjusted dephasing such that MR signals that are shown as light regions in the image 42 are acquired from regions around the particles. The particle is therefore imaged by making a region around the particle visible. The particle is thus clearly identifiable. A confusion with other structures that likewise lead to hypointense image contrast is in particular avoided.

By acquiring images for different dephasing stages, on the one hand a dephasing strength at which the particle can be imaged with particularly good contrast can be found for different dephasing stages; on the other hand a combined image 43 can be determined from the exposures for different dephasing stages. Depending on the configuration of the combination, the particle cardiac noise thereby be shown with positive or negative contrast. In particular, it can be separated and differentiated from remaining imaged structures.

For the images of the particle that are shown in FIG. 4, FIG. 5 shows corresponding simulations that were numerically calculated for the same dephasing strengths. From these it is clear that the interference field of the particle to be imaged can be described as a dipole field, and that the adjusted dephasing leads to an increase of the image intensity in regions around the particle. In particular, the particle to be imaged can be unambiguously identified via the intensity distribution in the combined image 53 which, like the image 43, shows a difference image.

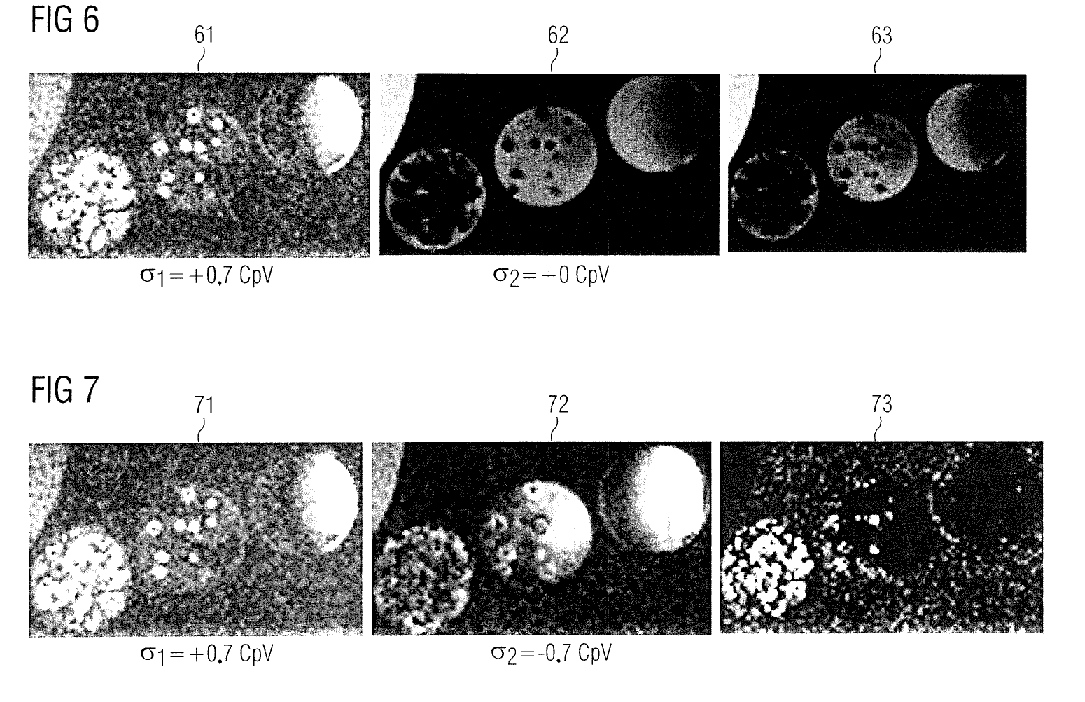

The images shown in FIG. 6 and FIG. 7 show transverse images of three sample vessels, wherein the sample vessels contain particles in the form of hollow spheres in different densities. The left vessel contains approximately 1000 hollow spheres, the middle vessel approximately 100 hollow spheres and the right vessel approximately 10 hollow spheres. In FIG. 6 the image 61 reconstructed from the first gradient echo was acquired at a first dephasing strength σ₁=+0.7 CpV and the image 62 reconstructed from the second gradient echo was acquired for a dephasing strength σ₂=−0.7 CpV. The second dephasing gradient was consequently adjusted such that a rephasing of the transverse magnetization occurred, such that the resulting second dephasing is equal to zero. The regions in the image 62 in which hollow spheres are located are accordingly shown as hypointense or dark regions. In contrast to this, the small hollow spheres are clearly shown with positive contrast in image 61 with positive dephasing strength. In image 62 the hollow spheres can only be differentiated from voids with difficulty (which voids were caused by other structures). Image 63 in turn depicts a difference image of the images 61 and 62.

The images 71 and 72 shown in FIG. 7 were in turn reconstructed for the first or, respectively, second echo and acquired with a dephasing strength of σ₁=+0.7 CpV or, respectively, σ₂=−0.7 CpV. The images clearly show that the different strength of the dephasing leads to imaging of the particles with different image contrast. In the corresponding difference image 73 the particles are clearly depicted as raised and contrasted from the remaining structures, and thus can be identified in a simple manner.

The method described herein is therefore suitable for a localization of particles in an examination subject that is essentially free of movement artifacts. Different dephasing stages within a gradient echo measurement can be measured with the method, which is connected with a significant time savings. The measurement of the echoes in very short time intervals avoids measurement errors that can be caused by movements of the examination subject. As shown, a depiction of the particles with increased contrast can be achieved by a targeted combination of the MR images acquired for different dephasing stages.

Although modifications and changes may be suggested by those skilled in the art, it is the intention of the inventor to embody within the patent warranted hereon all changes and modifications as reasonably and properly come within the scope of his contribution to the art.

I claim as my invention:

1. A method for imaging a particle located in an examination subject by implementing a magnetic resonance image data acquisition sequence in which at least a first gradient echo and a second gradient echo are acquired following a single excitation pulse while the examination subject is located in an applied basic magnetic field, said particle in said applied basic magnetic field causing a magnetic interference field, said magnetic resonance image data acquisition sequence comprising the steps of:
radiating a radio-frequency (RF) pulse into the subject to generate a transverse magnetization in the subject with respect to a magnetization in the subject produced by the basic magnetic field;
shifting a first dephasing gradient to adjust a first dephasing of said transverse magnetization;
acquiring said first gradient echo;
shifting a second dephasing gradient to adjust a second dephasing of the transverse magnetization that is different from said first dephasing;
acquiring said second gradient echo; and
shifting said first and second dephasing gradients to cause a dephasing of the transverse magnetization caused by the interference field produced by the particle to be at least partially compensated in a region around or within the particle during acquisition of at least one of said first and second gradient echoes.

2. A method as claimed in claim 1 comprising shifting said first and second dephasing gradients along a same gradient direction with the same polarity or opposite polarity.

3. A method as claimed in claim 1 wherein said magnetic resonance image data sequence has a slice selection direction, a frequency coding direction and a phase coding direction associated therewith, and comprising shifting said first and second dephasing gradients along one of said slice selection direction, said frequency coding direction, or said phase coding direction.

4. A method as claimed in claim 1 comprising shifting said first and second dephasing gradients to cause the second dephasing gradient to compensate said first dephasing and to generate said second dephasing.

5. A method as claimed in claim 1 comprising shifting said first and second dephasing gradients to cause a gradient of the phase position of the transverse magnetization to have a polarity sign after adjustment of said first dephasing that is inverted with respect to a polarity sign after adjustment of said second dephasing.

6. A method as claimed in claim 1 comprising setting said first or second dephasing to zero to cause the transverse magnetization to be rephased after the first dephasing gradient or the second dephasing gradient.

7. A method as claimed in claim 1 comprising configuring said first dephasing gradient to comprise a dephasing gradient and a rephasing gradient, each having a gradient moment, and adjusting the first dephasing of the transverse magnetization by adjusting a difference between the gradient moment of the rephasing gradient of the first dephasing gradient and the gradient moment of the dephasing gradient of the first dephasing gradient.

8. A method as claimed in claim 7 wherein said magnetic resonance image data acquisition sequence has a slice selection direction associated therewith, and comprising shifting the dephasing gradient of the first dephasing gradient in the slice selection direction during radiation of said RF pulse.

9. A method as claimed in claim 7 comprising shifting the rephasing gradient of the first dephasing gradient and the second dephasing gradient in the same direction or in opposite directions.

10. A method as claimed in claim 1 comprising, in said magnetic resonance image data acquisition sequence, following acquisition of said second gradient echo, implementing a plurality of additional readouts each comprising shifting of a dephasing gradient and acquisition of a subsequent gradient echo, to cause, in each readout, a different dephasing of the transverse magnetization, causing a different dephasing stage to be acquired with each gradient echo in the respective additional readouts.

11. A method as claimed in claim 1 comprising for each adjusted dephasing, reconstructing image data representing the particle or a region around the particle with different contrast, from the at least first and second gradient echoes.

12. A method as claimed in claim 11 comprising generating combined image data by addition or subtraction of the respective sets of image data for at least two different dephasings.

13. A method as claimed in claim 1 wherein said particle is a magnetically active particle comprising iron oxide.

14. A magnetic resonance system comprising:
a magnetic resonance data acquisition unit operable to image a particle located in an examination subject by implementing a magnetic resonance image data acquisition sequence in which at least a first gradient echo and a second gradient echo are acquired following a single excitation pulse while the examination subject is located in an applied basic magnetic field, said particle in said applied basic magnetic field causing a magnetic interference field; and
a computerized control unit configured to operate said data acquisition unit to radiate a radio-frequency (RF) pulse into the subject to generate a transverse magnetization in the subject with respect to a magnetization in the subject produced by the basic magnetic field, shift a first dephasing gradient to adjust a first dephasing of said transverse magnetization, acquire said first gradient echo, shift a second dephasing gradient to adjust a second dephasing of the transverse magnetization that is different from said first dephasing, acquire said second gradient echo, and shift said first and second dephasing gradients to cause a dephasing of the transverse magnetization caused by the interference field produced by the particle to be at least partially compensated in a region around or within the particle during acquisition of at least one of said first and second gradient echoes.

15. A non-transitory computer-readable data storage medium encoded with programming instructions, said medium being loaded into a computer system of a magnetic resonance system comprising a magnetic resonance data acquisition unit, and said programming instructions causing said computer system to operate said data acquisition system to:
radiate a radio-frequency (RF) pulse into the subject to generate a transverse magnetization in the subject with respect to a magnetization in the subject produced by the basic magnetic field;
shift a first dephasing gradient to adjust a first dephasing of said transverse magnetization;
acquire said first gradient echo;
shift a second dephasing gradient to adjust a second dephasing of the transverse magnetization that is different from said first dephasing;
acquire said second gradient echo; and
shift said first and second dephasing gradients to cause a dephasing of the transverse magnetization caused by the interference field produced by the particle to be at least partially compensated in a region around or within the particle during acquisition of at least one of said first and second gradient echoes.
